(19) United States
(12) Patent Application Publication
(10) Pub. No.: US 2024/0088854 A1
(43) Pub. Date: Mar. 14, 2024

(54) VARIABLE RESISTOR CIRCUIT, RESISTOR VOLTAGE DIVIDER CIRCUIT, DIFFERENTIAL AMPLIFIER, AND MOTOR DRIVER

(71) Applicant: ROHM CO., LTD., Kyoto (JP)

(72) Inventor: Takashige MIYASHITA, Kyoto (JP)

(21) Appl. No.: 18/462,594

(22) Filed: Sep. 7, 2023

(30) Foreign Application Priority Data
Sep. 13, 2022 (JP) 2022-145467

(51) Int. Cl. H03F 3/45; H03F 1/02; H03F 1/34

(52) U.S. Cl. CPC H03F 3/45475; H03F 1/0233; H03F 1/342; H03F 2203/45528

(57) ABSTRACT

A variable resistor circuit is configured to change its resistance value based on the resistance value change ratio given by (Δ/RA)×100% in each resistor unit circuit, where A represents the resistance value change in each resistor unit circuit between a first combined resistance value of that resistor unit circuit including at least the resistance value of the resistor unit circuit with a MOS switch off and a second combined resistance value of the resistor unit circuit including at least the resistance value of the resistor unit circuit with the MOS switch on, and RA represents the sum of the total combined resistance values of the plurality of resistor unit circuits with the MOS switches in all the resistor unit circuits off and the resistance value of the third resistor.

This application is based on the following Japanese Patent Application, the contents of which are hereby incorporated by reference:

Japanese Patent Application published as No. 2022-145467, filed on Sep. 13, 2022.

### BACKGROUND OF THE INVENTION

### 1. Technical Field

The present disclosure relates to a variable resistor circuit.

### 2. Description of Related Art

Conventionally, variable resistor circuits are used in a variety of applications (see, for example, Japanese Unexamined Patent Application published as No. 2020-96233).

### BRIEF DESCRIPTION OF THE DRAWINGS

FIG. 1 is a diagram showing the configuration of a differential amplifier.

FIG. 2 is a diagram showing the configuration of part of a variable resistor circuit according to a first comparative example.

FIG. 3 is a diagram showing the configuration of part of a variable resistor circuit according to a second comparative example.

FIG. 4 is a diagram showing the configuration of a variable resistor circuit according to an exemplary embodiment of the present disclosure.

FIG. 5 is a diagram showing a more specific circuit configuration of the variable resistor circuit.

FIG. 6 is a schematic diagram showing one example of a sliding contact layout for resistive elements.

FIG. 7 is a diagram showing the configuration of a variable resistor circuit according to a modified example.

FIG. 8 is a diagram showing an example of how a resistor unit circuit is optimized.

FIG. 9 is a diagram showing the configuration of the variable resistor circuit before and after optimization.

FIG. 10 is a diagram showing the configuration of a resistor voltage divider circuit according to another exemplary embodiment of the present disclosure.

FIG. 11 is a diagram showing a more specific circuit configuration of the resistor voltage divider circuit.

FIG. 12 is a diagram showing the configuration of a resistor voltage divider circuit according to a modified example.

FIG. 13 is a diagram showing the configuration of a motor driving system.

### DETAILED DESCRIPTION OF PREFERRED EMBODIMENTS

Exemplary embodiments of the present disclosure will be described below with reference to the accompanying drawings.

<Differential Amplifier>

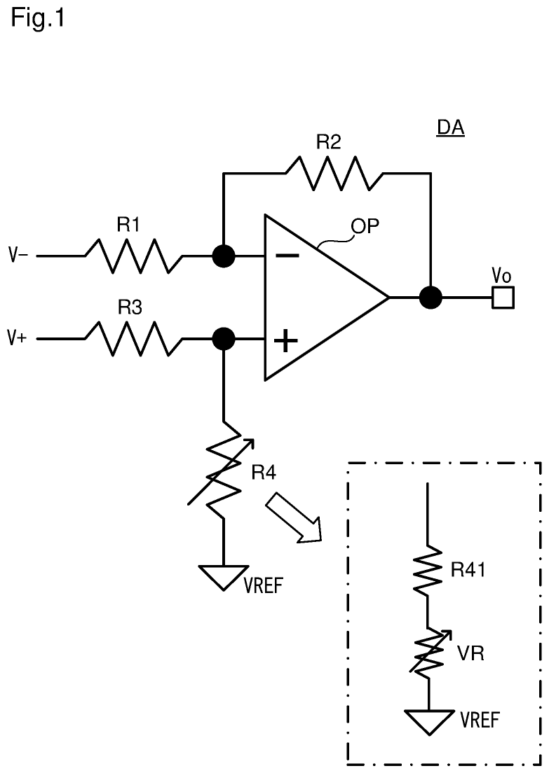

Here, a differential amplifier will be described. FIG. 1 is a diagram showing the configuration of a differential amplifier DA. The differential amplifier DA includes an operational amplifier OP, an input resistor R1, a feedback resistor R2, an input resistor R3, and a reference resistor R4. To the first terminal of the input resistor R1, an application terminal for a negative input voltage V− is connected. The second terminal of the input resistor R1 is connected to the inverting input terminal (−) of the operational amplifier OP. To the first terminal of the input resistor R3, an application terminal for a positive input voltage V+ is connected. The second terminal of the input resistor R3 is connected to the non-inverting input terminal (+) of the operational amplifier OP. The first terminal of the reference resistor R4 is, along with the second terminal of the input resistor R3, connected to the non-inverting input terminal (+) of the operational amplifier OP. The second terminal of the reference resistor R4 is connected to an application terminal for a reference voltage VREF. The first terminal of the feedback resistor R2 is connected to the output terminal of the operational amplifier OP. The second terminal of the feedback resistor R2 is, along with the second terminal of the input resistor R1, connected to the inverting input terminal of the operational amplifier OP. The resistance values are set such that R1=R3 and that R2=R4.

The differential amplifier DA amplifies the difference between the positive and negative input voltages V+ and V− at a differential gain determined by the resistance values of the resistors R1 to R4 to output an output voltage Vo. Here, ideally, when the differential amplifier DA is fed with positive and negative input voltages V+ and V− with an equal value, the output voltage Vo should be 0; in reality, however, the output voltage Vo deviates from 0 due to variations in the resistors R1 to R4. Thus, with the differential amplifier DA, it is important to increase the value of what is called CMRR (common mode rejection ratio). Here, CMRR=Differential Gain/Common Mode Gain. CMRR is determined by the resistance values of the resistors R1 to R4. To increase the value of CMRR requires a high degree of matching among the resistance values.

Thus, in the differential amplifier DA shown in FIG. 1, out of the resistors R1 to R4, the reference resistor R4 is configured as a variable resistor of which the resistance value can be changed so that, through adjustment of the resistance value of the reference resistor R4, trimming can be performed to increase the value of the CMRR. For example, it is possible to obtain a CMRR >70 db.

In practice, as shown in FIG. 1, the reference resistor R4 is configured with a resistor R41 and a variable resistor circuit VR connected in series. For example, the resistance values are set such that, while R1=R2=R3=5 kΩ, R41=4.5 kΩ and VR=0.5 kΩ. In the differential amplifier DA, what matters is the matching among R1 to R3 and R41, and R1 to R3 and R41 are given a resistive element size significantly larger than that of the resistive element used in the variable resistor circuit VR. The larger element size also helps reduce 1/f noise.

<Variable Resistor of a Comparative Example>

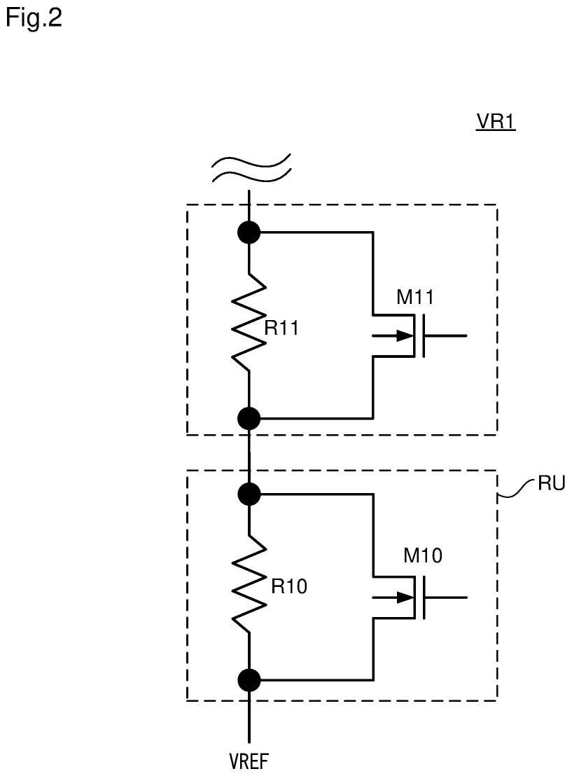

FIG. 2 is a diagram showing the configuration of part of the variable resistor circuit VR1 according to a first comparative example. The variable resistor circuit VR1 is configured with resistor unit circuits RU connected in series. The resistor unit circuits RU are configured with, for example, a resistor R10 and a MOS switch M10 connected in parallel, a resistor R11 and a MOS switch M11 connected in parallel, and so forth. The MOS switches M10, M11, and the like are each configured as a MOSFET (metal-oxide-semiconductor field-effect transistor). In FIG. 2, each MOS switch is configured as an NMOS transistor (n-channel MOSFET).

Thus, turning on the MOS switches M10, M11, and the like leaves the resistors R10, R11, and the like bypassed, and turning off those switches enables the resistors R10, R11, and the like. In this way, by making the resistance value of each resistor unit circuit RU variable, it is possible to vary the resistance value of the entire variable resistor circuit VR1.

The variable resistor circuit VR1 is designed to use the absolute values of the combined resistances of the resistance values of the resistors R10, R11, and the like and the on-resistances of the MOS switches M10, M11, and the like connected in parallel respectively. However, the on-resistances of the MOS switches need to be sufficiently lower than the resistance values of the resistors connected in parallel to them such that, for example, On-Resistance of M10<<R10, On-Resistance of M11<<R11, and so forth. To improve the accuracy of the variable resistor circuit VR1, the resistance values of the resistors R10, R11, and the like need to be low, and the on-resistances of the MOS switches M10, M11, and the like need to be even lower. This, inconveniently, results in an increased layout area of the MOS switch.

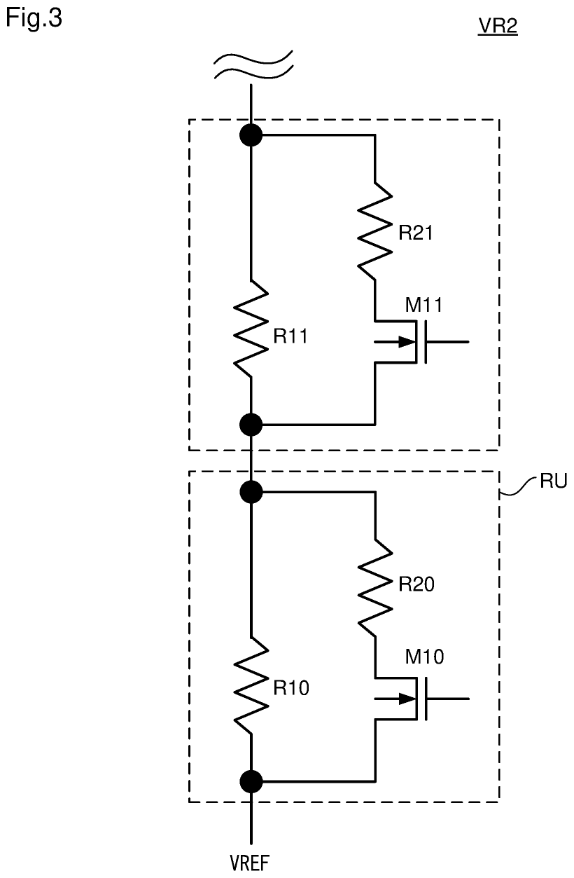

FIG. 3 is a diagram showing the configuration of part of the variable resistor circuit VR2 according to a second comparative example. The difference of the variable resistor circuit VR2 from the variable resistor circuit VR1 is that the resistor unit circuits RU are configured with resistors R10, R11, and the like respectively connected in parallel with resistors R20, R21, and the like connected in series with the MOS switches M10, M11, and the like respectively. The MOS switches M10, M11, and the like can each be turned on and off to make the resistance value of each of the resistor unit circuit RU variable, and hence to make the resistance value of the entire variable resistor circuit VR2 variable.

The variable resistor circuit VR2 is configured to use the absolute value of the combined resistance value of the resistance values of the resistors R10, R11, and the like, the resistance values of the resistors R20, R21, and the like, and the on-resistances of the MOS switches M10, M11, and the like. To improve the accuracy of the variable resistor circuit VR2, the resistors R10, R11, and the like with low resistance values need to be connected in parallel with the resistors R20, R21, and the like with low resistance values. While the on-resistances of the MOS switches M10, M11, and the like can be about 5% of the resistance values of the resistors R20, R21, and the like that are connected in series with them, those on-resistances need to be low. This, inconveniently, results in an increased layout area of the MOS switch.

In particular, when the variable resistor circuits VR1 and VR2 are applied to the reference resistor R4 in the differential amplifier DA described earlier, the value of the reference resistor R4 needs to be low to reduce thermal noise; thus, the inconvenience mentioned above is more notable.

<Variable Resistor Circuit According to the Present Disclosure>

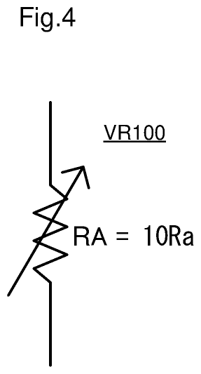

To provide a solution to the inconvenience mentioned above, an embodiment according to the present disclosure will be presented below. FIG. 4 is a diagram showing the configuration of a variable resistor circuit VR100 according to an exemplary embodiment of the present disclosure. Here, the resistance value of the variable resistor circuit VR100 is RA and, as will be described later, assuming that the unit resistance is Ra, the resistance value can be varied so as to decrease from RA=10 Ra.

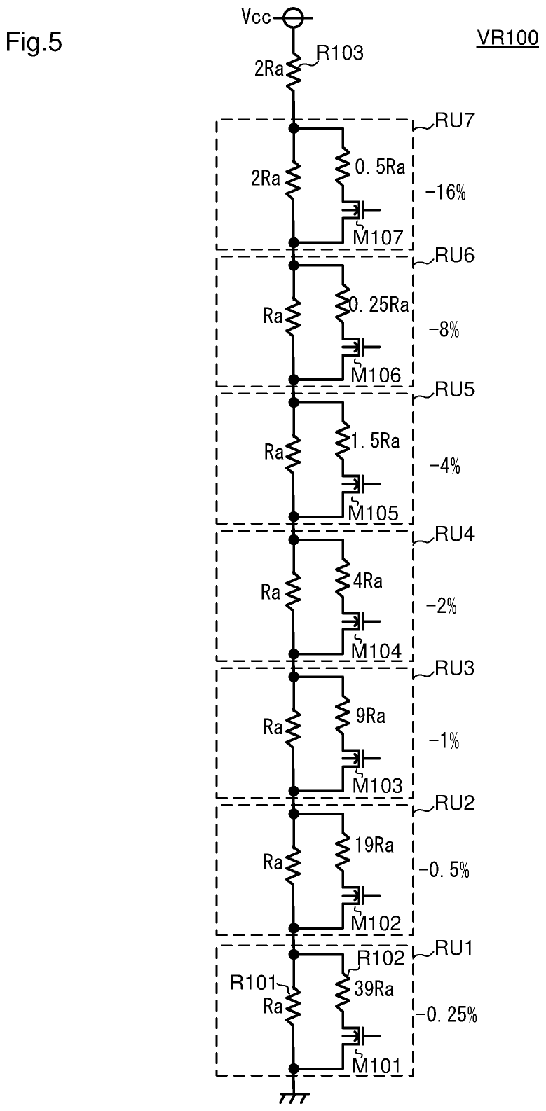

FIG. 5 is a diagram showing a more specific circuit configuration of the variable resistor circuit VR100. As shown in FIG. 5, the variable resistor circuit VR100 includes resistor unit circuits RU1 to RU7. The resistor unit circuits RU1 to RU7 are connected in series in this order from the low-potential (GND) side to the high-potential (predetermined voltage Vcc) side. That is, the resistor unit circuit RU1 is at the lowest-potential end, and the resistor unit circuit RU7 is at the highest-potential end.

The resistor unit circuits RU1 to RU7 are each configured with a first resistor R101 connected in parallel with a second resistor R102 connected in series with one of MOS switches M101 to M107. The MOS switches M101 to M107 are configured as NMOS transistors.

The variable resistor circuit VR100 also includes a third resistor R103. The third resistor R103 is connected between the resistor unit circuit RU7 and an application terminal for the predetermined voltage Vcc. That is, the third resistor R103 is connected in series with the resistor unit circuit RU7.

When the MOS switches M101 to M107 are off, the combined resistance value of each of the resistor unit circuits RU1 to RU7 equals the resistance value of the first resistor R101. The resistance value of the first resistor R101 in each of the resistor unit circuits RU1 to RU6 is Ra, and the resistance value of the first resistor R101 in the resistor unit circuit RU7 is 2 Ra. The resistance value of the third resistor R103 is 2 Ra. Thus, when the MOS switches M101 to M107 in all the resistor unit circuits RU1 to RU7 are off, the sum of the resistance values of the first resistors R101 in the resistor unit circuits RU1 to RU7 and the resistance value of the third resistor R103 is the resistance value RA of the variable resistor circuit VR100. That is, RA=6×Ra+2 Ra+2 Ra=10 Ra (FIG. 4).

In the resistor unit circuit RU1, R101=Ra and R102=39 Ra. Thus, when the MOS switch M101 is off, the combined resistance value of the resistor unit circuit RU1 is Ra, and when the MOS switch M101 is on, the combined resistance value of the resistor unit circuit RU1 is 0.975 Ra. That is, the resistance value change Δ at the off-to-on transition equals −0.025 Ra. Since RA=10 Ra, Δ=−0.0025 RA; thus, the resistance value change ratio equals (Δ/RA)×100%=−0.25%.

In the resistor unit circuit RU2, R101=Ra, and R102=19 Ra. Thus, when the MOS switch M102 is off, the combined resistance value of the resistor unit circuit RU2 is Ra, and, when the MOS switch M102 is on, the combined resistance value of the resistor unit circuit RU2 is 0.95 Ra. That is, the resistance value change Δ equals −0.05 Ra=−0.005 RA; thus, the resistance value change ratio equals −0.5%.

In the resistor unit circuit RU3, R101=Ra, and R102=9 Ra. Thus, when the MOS switch M103 is off, the combined resistance value of the resistor unit circuit RU3 is Ra, and, when the MOS switch M103 is on, the combined resistance value of the resistor unit circuit RU3 is 0.9 Ra. That is, the resistance value change Δ equals −0.1 Ra=−0.01 RA; thus, the resistance value change ratio equals −1%.

In the resistor unit circuit RU4, R101=Ra, and R102=4 Ra. Thus, when the MOS switch M104 is off, the combined resistance value of the resistor unit circuit RU4 is Ra, and when the MOS switch M104 is on, the combined resistance value of the resistor unit circuit RU4 is 0.8 Ra. That is, the resistance value change Δ equals −0.2 Ra=−0.02 RA; thus, resistance value change ratio equals −2%.

In the resistor unit circuit RU5, R101=Ra, and R102=1.5 Ra. Thus, when the MOS switch M105 is off, the combined resistance value of the resistor unit circuit RU5 is Ra, and when the MOS switch M105 is on, the combined resistance value of the resistor unit circuit RU5 is 0.6 Ra. That is, the resistance value change Δ equals −0.4 Ra=−0.04 RA; thus, the resistance value change ratio equals −4%.

In the resistor unit circuit RU6, R101=Ra, and R102=0.25 Ra. Thus, when the MOS switch M106 is off, the combined resistance value of the resistor unit circuit RU6 is Ra, and when the MOS switch M106 is on, the combined resistance value of the resistor unit circuit RU6 is 0.2 Ra. That is, the resistance value change Δ equals −0.8 Ra=−0.08 RA; thus, the resistance value change ratio equals −8%.

In the resistor unit circuit RU7, R101=2Ra, and R102=0.5 Ra. Thus, when the MOS switch M107 is off, the combined resistance value of the resistor unit circuit RU7 is 2Ra, and when the MOS switch M107 is on, the combined resistance value of the resistor unit circuit RU7 is 0.4 Ra. That is, the resistance value change Δ equals −1.6 Ra=−0.16 RA; thus, the resistance value change ratio equals −16%.

In this way, starting with the resistance value RA (=10 Ra) of the variable resistor circuit VR100 with all the MOS switches M101 to M107 in the resistor unit circuits RU1 to RU7 off, it can be changed from −0.25% to −31.75% at a minimum resolution (1LSB) of −0.25% by turning on one-by-one the MOS switches M101 to M107 in the resistor unit circuits RU1 to RU7.

Assuming that the resistor unit circuits RU1 to RU7 correspond to a first to a seventh bit respectively, RA=10 Ra+(2⁰×(−0.25%)×b0+2¹×(−0.25%)×b1+2²×(−0.25%)×b2+2³×(−0.25%)×b3+2⁴×(−0.25%)×b4+2⁵×(−0.25%)×b5+2⁶×(−0.25%)×b6)×10 Ra. Here, b0 to b6 are the values at the first to seventh bits respectively. When the MOS switches M101 to M107 are off, the corresponding bit values are 0, and when M101 to M107 are on, the corresponding bit values are 1.

Thus, it is possible to change the resistance value RA of the variable resistor circuit VR100 in accordance with 7-bit digital data, and this is particularly effective for trimming purposes.

In this way, this embodiment is characterized in that the resistance value change Δ is obtained by turning on the MOS switches M101 to M107. While the comparative example described earlier is based on an absolute value design, this embodiment is based on a relative value design. Connecting the first resistor R101 with a high resistance value in parallel with the second resistor R102 with a high resistance value connected in series with one of the MOS switches M101 to M107 makes it possible to obtain small changes A. Here, the on-resistances of the MOS switches M101 to M107 may each be about 5% of the resistance value of the second resistor R102 that is connected in series with them; this helps suppress an increase in the layout area of the MOS switches M101 to M107.

With the absolute value design, lower resistance values are obtained by parallel connection, and this requires a larger number of resistors. In contrast, this embodiment aims at obtaining ΔR, and this requires a smaller number of resistors. The variable resistor circuit VR100 shown in FIG. 5 requires 90 basic resistors Ra.

In this embodiment, the first resistor R101, the second resistor 102, and the third resistor R103 are each configured with a single unit resistance Ra or a combination of a plurality of unit resistances Ra. For example, in the configuration shown in FIG. 5, the first resistor R101 in the resistor unit circuit RU6 has a resistance value of Ra and is configured with a single unit resistance Ra. The second resistor R102 in the resistor unit circuit RU6 has a resistance value of 0.25 Ra and is configured with four unit resistances Ra connected in parallel. That is, in this embodiment, all the resistive elements used are of a single kind.

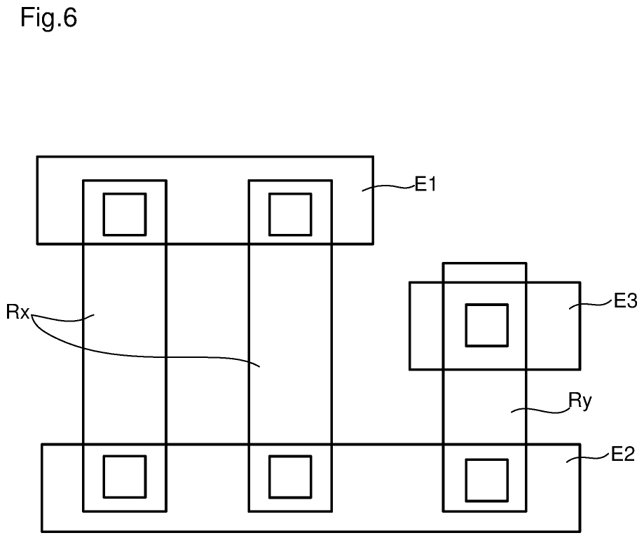

Here, FIG. 6 is a schematic diagram showing one example of a sliding contact layout for resistive elements. A sliding contact is a method of setting a resistance value by sliding an electrode in a direction in which a resistive element (such as polysilicon resistor) extends. The example in FIG. 6 includes resistive elements Rx with the same resistance value and a resistive element Ry with a resistance value different from that of Rx along with electrodes E1 to E3. With this embodiment, since all the resistive elements are of a single kind, there is no need for the sliding contact layout. This helps improve the parity among resistors in, and hence improve the accuracy of, the variable resistor circuit.

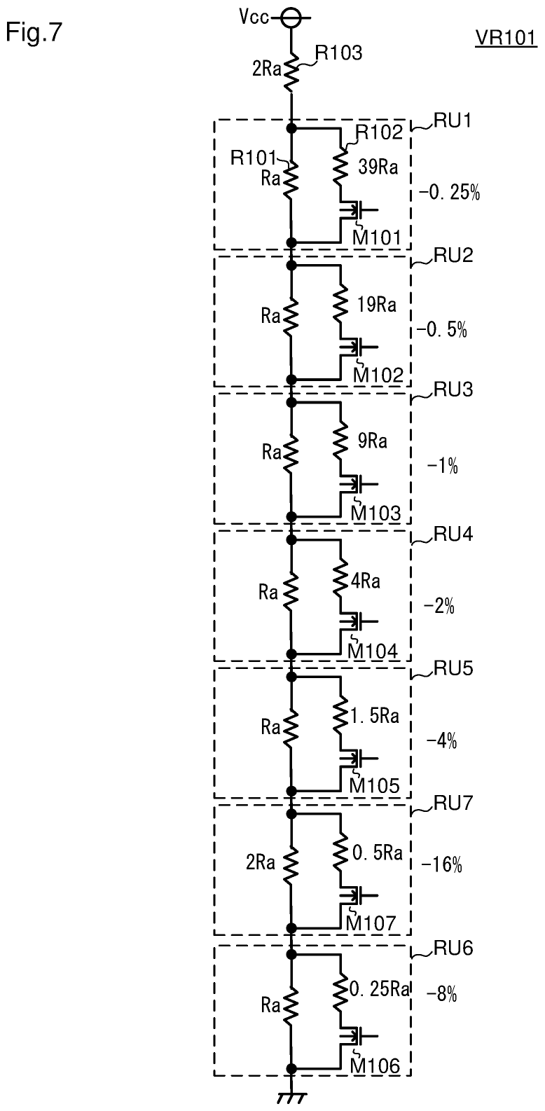

FIG. 7 is a diagram showing the configuration of a variable resistor circuit VR101 according to a modified example of the variable resistor circuit VR100 shown in FIG. 5. The difference of the variable resistor circuit VR101 from the variable resistor circuit VR100 is that it has resistor unit circuits RU1 to RU7 arrayed from the low-potential side to the high-potential side in increasing order of the resistance value of the second resistor R102 and connected in series. Thus, the resistor unit circuit RU6 of which the second resistor R102 has the lowest resistance value, namely 0.25 Ra, is arranged at the lowest-potential end, and the resistor unit circuit RU1 of which the second resistor R102 has the highest resistance value, namely 39 Ra, is arranged at the highest-potential end.

The on-resistances of the MOS switches M101 to M107 need to correspond to the second resistors R102 connected in series with the M101 to M107; thus, the lower the resistance value of the second resistor R102 is, the lower the on-resistances of the MOS switches M101 to M107 need to be. Thus, when the MOS switches M101 to M107 in all the resistor unit circuits RU1 to RU7 are of the same size, the lower the resistance value of the second resistor R102, the higher the Vgs (gate-source voltage) of the MOS switches M101 to M107 needs to be. Assuming that the gate voltages of the MOS switches M101 to M107 are the same among the resistor unit circuits RU1 to RU7, the closer to the lowest-potential end, the lower the resistance value of the second resistor R102 can be made, and the higher the Vgs of the MOS switches M101 to M107 can be made. This is because, the closer the MOS switches M101 to M107 are to the low-potential end, the lower their source voltages are.

<Optimization of Resistor Unit Circuit>

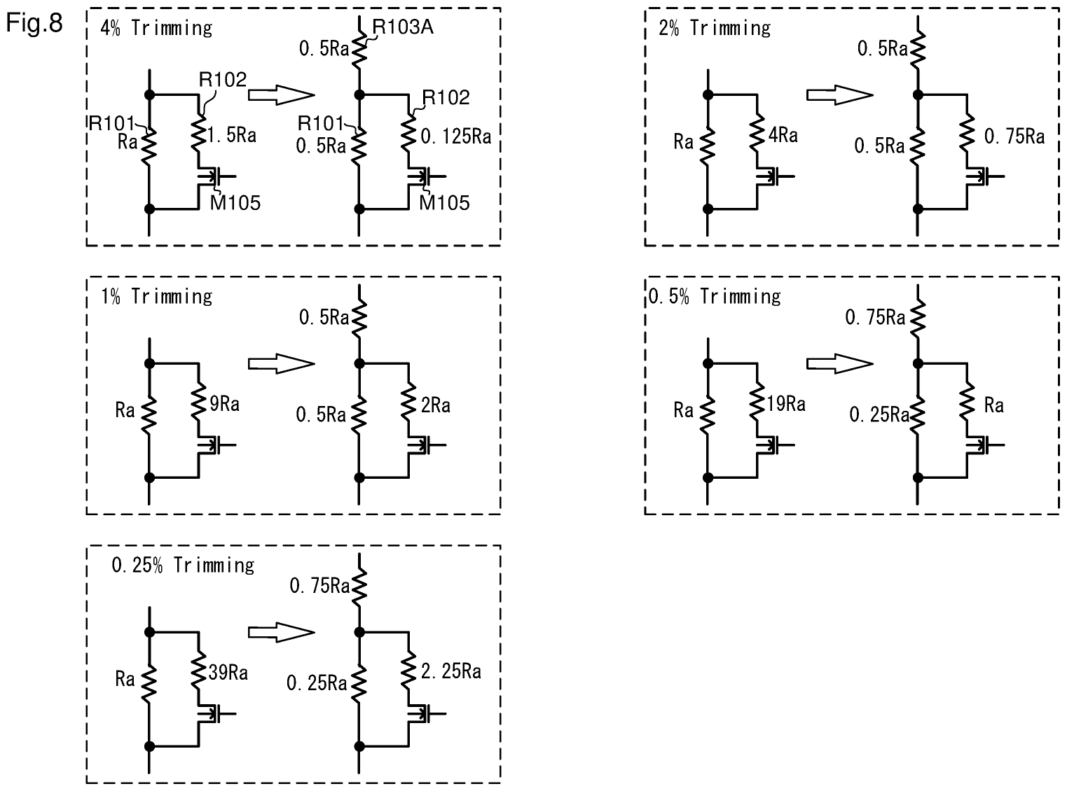

Next, a description will be given of an example of a design for further optimization of the resistor unit circuit in the variable resistor circuit VR100 configured as shown in FIG. 5. FIG. 8 is a diagram showing an example of how the resistor unit circuit is optimized.

In FIG. 8, in the resistor unit circuit RU5 with the resistance value change ratio of −4%, before optimization, the first resistor R101=Ra and the second resistor R102=1.5 Ra; after the optimization, R101=0.5 Ra and R102=0.125 Ra, and a resistance component R103A (=0.5 Ra) is connected in series with the resistor unit circuit RU5. The resistance component R103A is part of the third resistor R103. In this way, it is possible to lower the source voltages of the MOS switches M106 and M107 in the highest-bit resistor unit circuits RU6 and RU7. Also for the resistor unit circuit RU4 with the resistance value change ratio of −2% shown in FIG. 8, similar optimization is performed to reduce the source voltage.

In FIG. 8, in the resistor unit circuit RU3 with the resistance value change ratio of −1%, before the optimization, R101=Ra and R102=9 Ra; after optimization, R101=0.5 Ra and R102=2 Ra, and a resistance component R103A (=0.5 Ra) is connected in series with the resistor unit circuit RU3. In this way, the number of unit resistances Ra needed is reduced from ten to six. Also for the resistor unit circuits RU2 and RU1 with the resistance value change ratios of −0.5% and −0.25%, similar optimization is performed to reduce the number of unit resistances.

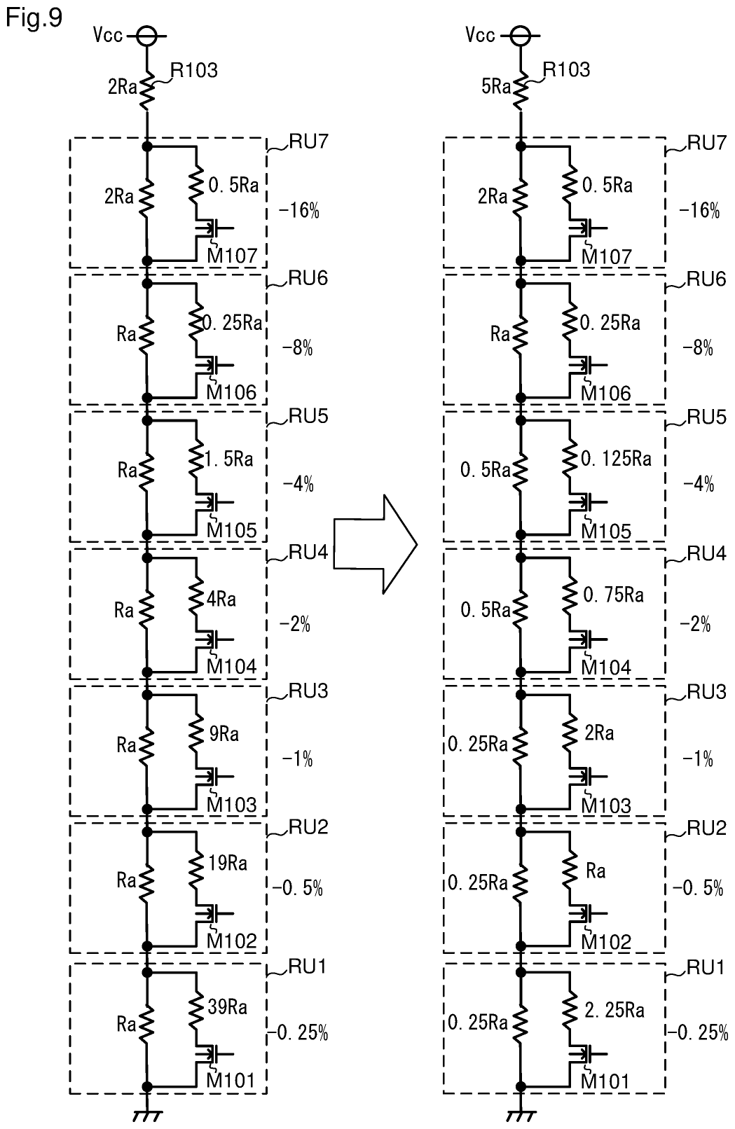

The results of such optimization are shown in FIG. 9. The configuration at left in FIG. 9 is the same as that shown in FIG. 5, and the configuration at right in FIG. 9 is one after optimization. In the optimized configuration, the resistance value of the third resistor R103 is the sum (=5 Ra) of the total resistance value of the resistance components R103A after optimization shown in FIG. 8 (=3 Ra) and the value of R103 before optimization (=2 Ra). With such optimization, the number of unit resistances Ra can be reduced from 90 to 49. Also, the source voltages of the highest-bit MOS switches M106 and M107 can be set lower.

<Application to a Resistor Voltage Divider Circuit>

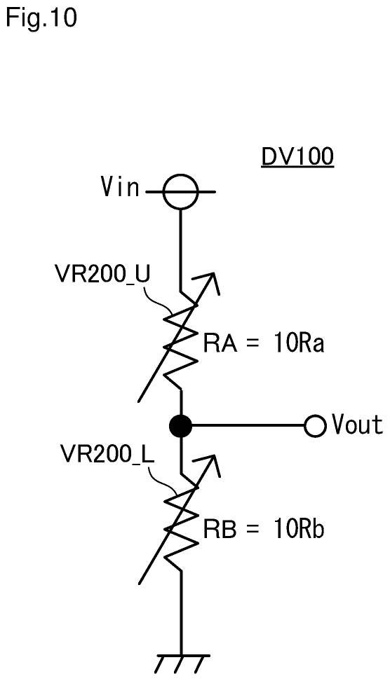

Next, a description will be given of an example where a variable resistor circuit is applied to a resistor voltage divider circuit. FIG. 10 is a diagram showing the configuration of a resistor voltage divider circuit DV100 according to another exemplary embodiment of the present disclosure.

The resistor voltage divider circuit DV100 is configured with a high-side variable resistor circuit VR200_U and a low-side variable resistor circuit VR200_L connected in series between an application terminal for the input voltage Vin and an application terminal for the ground potential. The high-side variable resistor circuit VR200_U is arranged on the high-potential side, and the low-side variable resistor circuit VR200_L is arranged on the low-potential side. From the node to which the variable resistor circuits VR200_U and VR200_L are connected, the output voltage Vout is output. The output voltage Vout is generated by dividing the input voltage Vin in accordance with the resistance values of the variable resistor circuits VR200_U and VR200_L.

The resistance value of the high-side variable resistor circuit VR200_U is RA, and, assuming that the unit resistance is Ra, the resistance value can be varied so as to decrease from RA=10 Ra. The resistance value of the low-side variable resistor circuit VR200_L is RB, and, assuming that the unit resistance is Rb, the resistance value can be varied so as to decrease from RB=10 Rb.

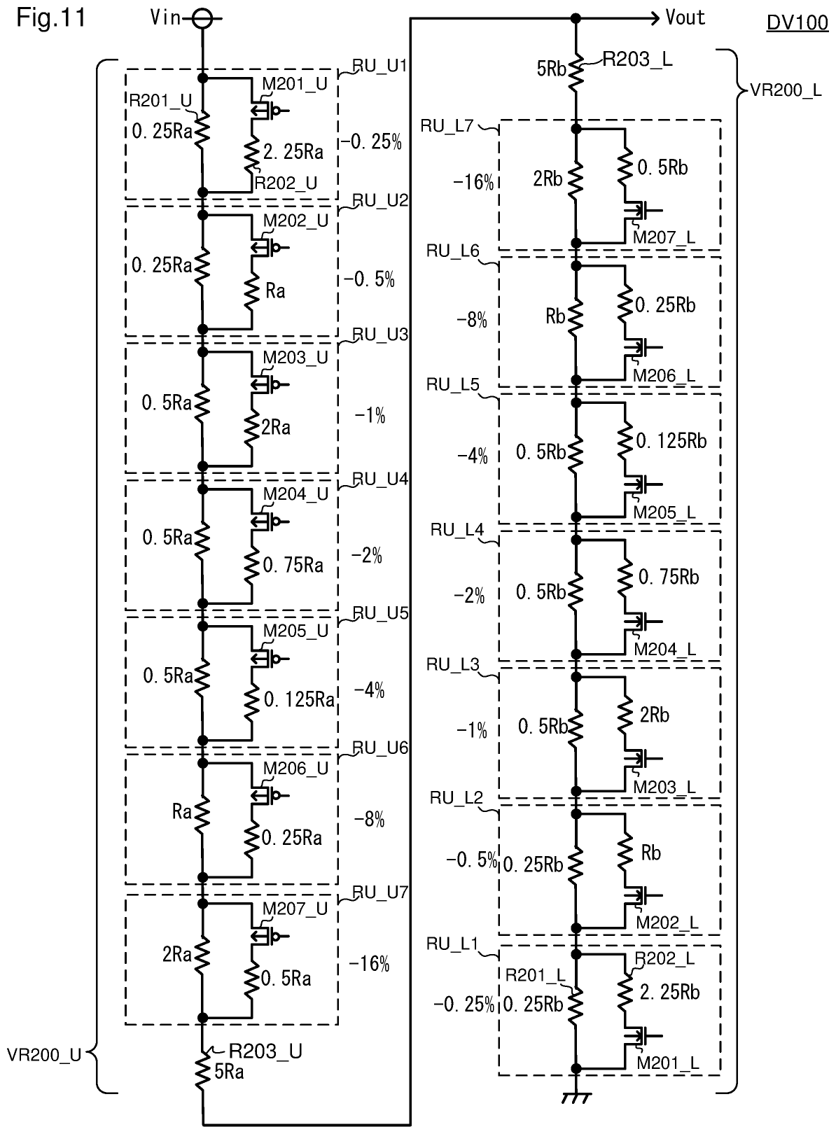

FIG. 11 is a diagram showing more specifically the circuit configuration of the resistor voltage divider circuit DV100 shown in FIG. 10.

As shown in FIG. 11, the high-side variable resistor circuit VR200_U is configured with high-side resistor unit circuits RU_U1 to RU_U7 connected in series. The high-side resistor unit circuits RU_U1 to RU_U7 are each configured with a first resistor R201_U connected in parallel with a second resistor R202_U connected in series with one of MOS switches M201_U to M207_U. The MOS switches M201_U to M207_U are configured as PMOS transistors (p-channel MOSFETs). The high-side resistor unit circuits RU_U1 to RU_U7 are arranged in this order from the high-potential side (input voltage Vin side) to the low-potential side. In the high-side variable resistor circuit VR200_U, a third resistor R203_U is connected in series with the low-potential side of the high-side resistor unit circuit RU_U7 at the lowest-potential end.

When all the MOS switches M201_U to M207_U are off, the resistance value RA of the high-side variable resistor circuit VR200_U is 10 Ra. The resistance value change ratios of the high-side resistor unit circuits RU_U1 to RU_U7 are −0.25%, −0.5%, −1%, −2%, −4%, −8%, and −16% respectively. Thus, assuming that 1LSB=−0.25%, the resistance value RA of the high-side variable resistor circuit VR200_U can be varied in accordance with 7-bit digital data.

As shown in FIG. 11, the low-side variable resistor circuit VR200_L is configured with low-side resistor unit circuits RU_L1 to RU_L7 connected in series. The low-side resistor unit circuits RU_L1 to RU_L7 are each configured with a first resistor R201_L connected in parallel with a second resistor R202_L connected in series with one of MOS switches M201_L to M207_L. The MOS switches M201_L to M207_L are configured as NMOS transistors. The low-side resistor unit circuits RU_L1 to RU_L7 are arranged in this order from the low-potential side (GND side) to the high-potential side. In the low-side variable resistor circuit VR200_L, a third resistor R203_L is connected in series with the high-potential side of the low-side resistor unit circuits RU_L7 at the highest-potential end.

When all the MOS switches M201_L to M207_L are off, the resistance value RB of the low-side variable resistor circuit VR200_L is 10 Rb. The resistance value change ratios of the low-side resistor unit circuits RU_L1 to RU_L7 are −0.25%, −0.5%, −1%, −2%, −4%, −8%, and −16% respectively. Thus, assuming that 1LSB=−0.25%, the resistance value RB of the low-side variable resistor circuit VR200_L can be varied in accordance with 7-bit digital data.

In the low-side variable resistor circuit VR200_L, the source voltages of the MOS switches M201_L to M207_L are low; thus, even if the MOS switches M201_L to M207_L are configured as NMOS transistors, it is possible to secure the Vgs to keep the on-resistances low. However, if, in the high-side variable resistor circuit VR200_U, the MOS switches M201_U to M207_U are configured as NMOS transistors, it is difficult to secure the Vgs; thus, the MOS switches M201_U to M207_U are configured as PMOS transistors.

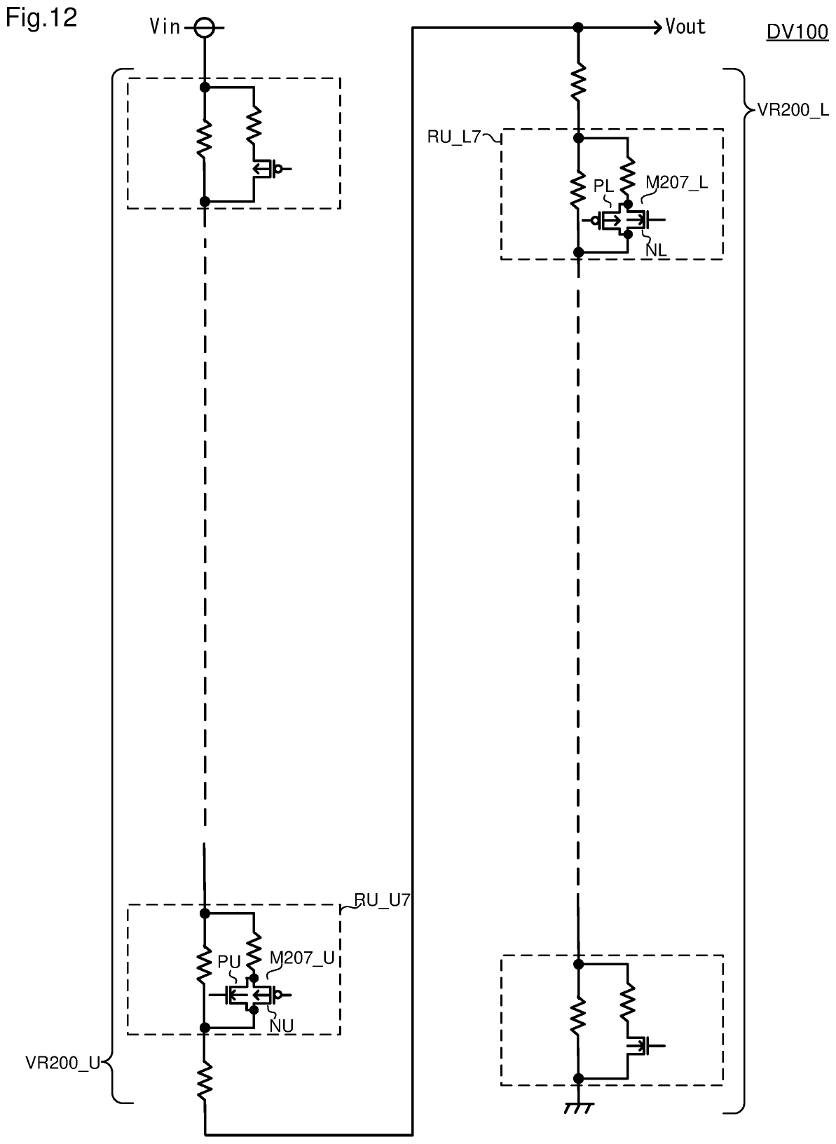

Still, in the low-potential-side resistor unit circuits in the high-side variable resistor circuit VR200_U, and in the high-potential-side resistor unit circuits in the low-side variable resistor circuit VR200_L, it may not be possible to secure a sufficient Vgs of the MOS switches to keep the on-resistances low. Thus, as shown in FIG. 12, in a low-potential-side resistor unit circuit (for example, RU_U7) in the high-side variable resistor circuit VR200_U, the MOS switch M207_U may be configured with a PMOS transistor PU and an NMOS transistor NU connected in parallel, and, in a high-potential-side resistor unit circuit (for example, RU_L7) in the low-side variable resistor circuit VR200_L, the MOS switch M207_L may be configured with an NMOS transistor NL and a PMOS transistor PL connected in parallel. This helps keep the on-resistances of the MOS switches low.

<Application to a Motor Driver>

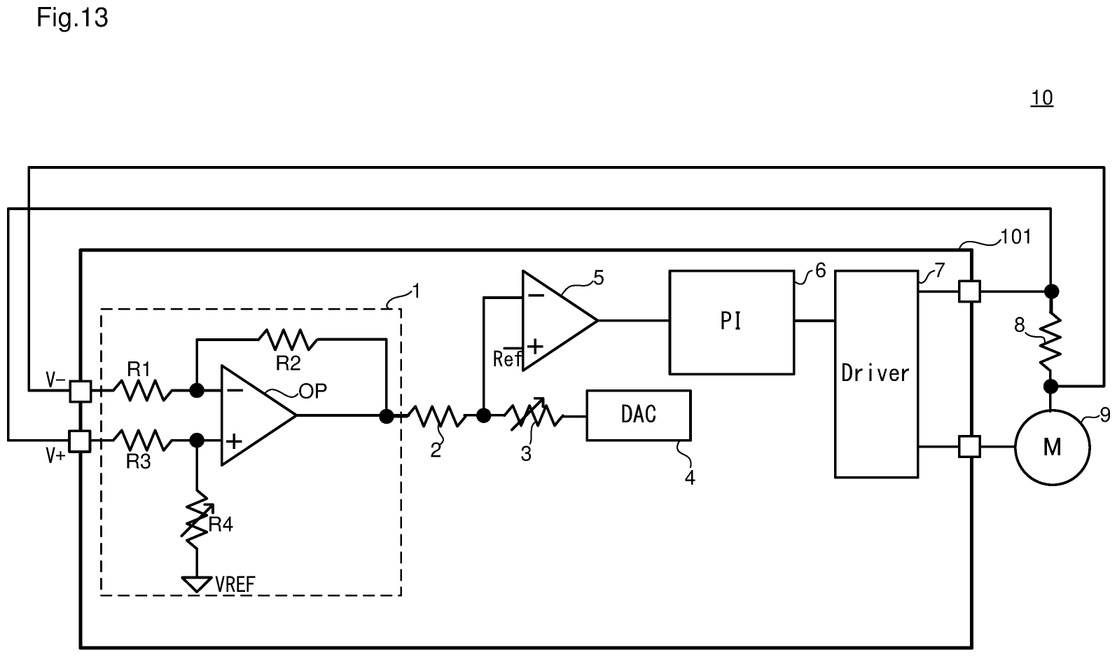

A variable resistor circuit according to the present disclosure finds many applications. As one example, a motor driver will be described. FIG. 13 is a diagram showing the configuration of a motor driving system 10. The motor driving system 10 includes a motor driver 101, a sense resistor 8, and a motor 9.

The motor 9 is a VCM (voice coil motor) included in an HDD (hard disc drive). The VCM is used to drive a magnetic head. The sense resistor 8 is a resistor for sensing a current passing through the motor 9.

The motor driver 101 includes a differential amplifier 1, a resistor 2, a variable resistor 3, a DAC (DA converter) 4, an error amplifier 5, a PI controller 6, and a driver 7, and drives the motor 9.

The first terminal of the sense resistor 8 is connected to the input terminal for a positive input voltage V+ of the differential amplifier 1. The second terminal of the sense resistor 8 is connected to the input terminal for a negative input voltage V− of the differential amplifier 1. In this way, the differential amplifier 1 is fed with a voltage across the sense resistor 8 and amplifies the fed voltage. The output terminal of the differential amplifier 1 is connected to the first terminal of the resistor 2. The second terminal of the resistor 2 is connected to the first terminal of the variable resistor 3 and to the inverting input terminal (−) of the error amplifier 5. The second terminal of the variable resistor 3 is connected to the output terminal of the DAC 4. The non-inverting input terminal (+) of the error amplifier 5 is fed with a reference voltage Ref. Based on the output of the DAC 4 and the reference voltage Ref, a target value for the current passing through the motor 9 is set. The output of the error amplifier 5 is fed to the PI controller 6. The PI controller 6, based on the input from the error amplifier 5, performs PI (proportional integral) control, and outputs a control signal to the driver 7. The driver 7, based on the control signal fed from the PI controller, passes a current through the motor 9 via the sense resistor 8. In this way, the current passing though the motor 9 can be controlled to remain at the target value.

The differential amplifier 1 is used as a current sense amplifier for sensing a current passing through the sense resistor 8. The differential amplifier 1 includes, as in FIG. 1 referred to previously, an operational amplifier OP, an input resistor R1, a feedback resistor R2, an input resistor R3, and a reference resistor R4. To meet performance required in a current sense amplifier, the resistance values of the resistors R1 to R4 need to be low for reduced thermal noise, and the value of CMRR needs to be high. Applying the variable resistor circuit to the reference resistor R4 helps improve the parity among resistors and increase the value of CMRR. Even with a reduced resistance value in the reference resistor R4, as described earlier, the variable resistor circuit according to the embodiment can achieve high accuracy while suppressing an increase in the layout area of MOS switches.

<Others>

The various technical features disclosed herein may be implemented in any other manners than in the embodiments described above, and allow for any modifications made without departure from their technical ingenuity. That is, the above embodiments should be understood to be in every aspect illustrative and not restrictive. The scope of the present invention is defined not by the description of the embodiments given above but by the appended claims, and should be understood to encompass any modifications made in a sense and scope equivalent to those of the claims.

<Notes>

According to one aspect of what is disclosed herein, a variable resistor circuit (VR100) includes a plurality of resistor unit circuits (RU1 to RU7) that are each configured with a first resistor (R101) connected in parallel with a second resistor (R102) connected in series with a MOS switch (one of M101 to M107), and a third resistor (R103) connected in series with the plurality of resistor unit circuits connected in series. When A represents the resistance value change in each resistor unit circuit between a first combined resistance value of that resistor unit circuit including at least the resistance value of the resistor unit circuit with the MOS switch off and a second combined resistance value of that resistor unit circuit including at least the resistance value of the resistor unit circuit with the MOS switch on, and RA represents the sum of the total combined resistance values of the plurality of resistor unit circuits with the MOS switches in all the resistor unit circuits off and the resistance value of the third resistor, the variable resistor circuit is configured to change its resistance value based on the resistance value change ratio given by (Δ/RA)×100% in each resistor unit circuit. (A first configuration, FIG. 5.)

In the first configuration described above, preferably, the resistance value of the variable resistor circuit is given by RA+(2⁰×(1LSB)×b0+ . . . +2^{(m-1)}×(1LSB)×bₘ₋₁)×RA, where 1LSB is the resistance value change ratio with the minimum absolute value, m is the number of resistor unit circuits, and bₙ₋₁ is the bit value indicating the on/off state of the MOS switch in the n-th bit resistor unit circuit (where n=1 to m). (A second configuration.)

In the first or second configuration described above, preferably, the first, second, and third resistors (R101, R102, and R103) are each configured with a single unit resistive element (Ra) or a combination of a plurality of unit resistive elements. (A third configuration.)

In any of the first to third configurations described above, preferably, the resistor unit circuits are arrayed from the low-potential side to the high-potential side in increasing order of the resistance value of the second resistor and are connected in series. (A fourth configuration, FIG. 7.)

In any of the first to fourth configurations described above, preferably, the combined resistance values of the plurality of resistor unit circuits with the MOS switches on are different from each other. (A fifth configuration.)

In any of the first to fifth configurations described above, preferably, in at least one of the resistor unit circuits, the first and second combined resistance values include a resistance component (R103A) connected in series with that resistor unit circuit, and the third resistor includes the resistance component. (A sixth configuration, FIGS. 8 and 9.)

According to another aspect of what is disclosed herein, a resistor voltage divider circuit (DV100) includes a high-side variable resistor circuit (VR200_U) arranged on the high-potential side and a low-side variable resistor circuit (VR200_L) arranged on the low-potential side. The high-side and low-side variable resistor circuits are configured with the variable resistor circuit according to any of the first to sixth configurations described above. (A seventh configuration, FIGS. 10 and 11.)

In the seventh configuration described above, preferably, at least one of the MOS switches (M201_U to M207_U) in the high-side variable resistor circuit is configured as a PMOS transistor, and at least one of the MOS switches (M201_L to M207_L) in the low-side variable resistor circuit is configured as an NMOS transistor. (An eighth configuration.)

In the eighth configuration described above, preferably, at least one of a low-potential-side MOS switch (M207_U) in the high-side variable resistor circuit and a high-potential-side MOS switch (M207_L) in the low-side variable resistor circuit is configured with a PMOS transistor (PU, PL) and an NMOS transistor (NU, NL) connected in parallel. (A ninth configuration, FIG. 12.)

According to yet another aspect of what is disclosed herein, a differential amplifier (1) includes an operational amplifier (OP), a first input resistor (R1) having a first terminal connected to an application terminal for a negative input voltage (V−) and a second terminal connected to the inverting input terminal of the operational amplifier, a feedback resistor (R2) having a first terminal connected to the output terminal of the operational amplifier and a second terminal connected to the second terminal of the first input resistor, a second input resistor (R3) having a first terminal connected an application terminal for a positive input voltage (V+) and a second terminal connected to the non-inverting input terminal of the operational amplifier, and a reference resistor (R4) having a first terminal connected to the second terminal of the second input resistor and a second terminal connected to an application terminal for a reference voltage (VREF). The reference resistor includes the variable resistor circuit according to any of the first to sixth configurations described above. (A tenth configuration, FIG. 13.)

In the tenth configuration described above, preferably, the application terminal for the positive input voltage is configured to be connectable to the first terminal of a sense resistor (8) for sensing a current, and the application terminal for the negative input voltage is configured to be connectable to the second terminal of the sense resistor. (An eleventh configuration.)

According to still another aspect of what is disclosed herein, a motor driver (101) includes the differential amplifier according to the eleventh configuration described above. The motor driver is configured to drive a voice coil motor (9). (A twelfth configuration.)

What is claimed is:

1. A variable resistor circuit comprising:
a plurality of resistor unit circuits that are each configured with a first resistor connected in parallel with a second resistor connected in series with a MOS switch; and
a third resistor connected in series with the plurality of resistor unit circuits connected in series,
wherein
when
Δ represents a resistance value change in each resistor unit circuit between
a first combined resistance value of said resistor unit circuit including at least a resistance value of the resistor unit circuit with the MOS switch off and
a second combined resistance value of said resistor unit circuit including at least a resistance value of the resistor unit circuit with the MOS switch on, and
RA represents a sum of the total combined resistance values of the plurality of resistor unit circuits with the MOS switches in all the resistor unit circuits off and a resistance value of the third resistor,
the variable resistor circuit is configured to change a resistance value thereof based on a resistance value change ratio given by (Δ/RA)×100% in each resistor unit circuit.

2. The variable resistor circuit according to claim 1,
wherein
the resistance value of the variable resistor circuit is given by RA+(2⁰×(1LSB)×b0+ . . . +2^{(m-1)}×(1LSB)×bₘ₋₁)×RA, where 1LSB is the resistance value change ratio with a minimum absolute value, m is a number of resistor unit circuits, and bₙ₋₁ is a bit value indicating an on/off state of the MOS switch in the n-th bit resistor unit circuit (where n=1 to m).

3. The variable resistor circuit according to claim 1,
wherein
the first, second, and third resistors are each configured with a single unit resistive element or a combination of a plurality of unit resistive elements.

4. The variable resistor circuit according to claim 1,
wherein
the resistor unit circuits are arrayed from a low-potential side to a high-potential side in increasing order of a resistance value of the second resistor and are connected in series.

5. The variable resistor circuit according to claim 1,
wherein
the combined resistance values of the plurality of resistor unit circuits with the MOS switches on are different from each other.

6. The variable resistor circuit according to claim 1,
wherein
in at least one of the resistor unit circuits, the first and second combined resistance values include a resistance component connected in series with said resistor unit circuit, and
the third resistor includes the resistance component.

7. A resistor voltage divider circuit comprising:
a high-side variable resistor circuit arranged on a high-potential side; and
a low-side variable resistor circuit arranged on a low-potential side,
wherein
the high-side and low-side variable resistor circuits are configured with the variable resistor circuit according to claim 1.

8. The resistor voltage divider circuit according to claim 7,
wherein
at least one of the MOS switches in the high-side variable resistor circuit is configured as a PMOS transistor, and at least one of the MOS switches in the low-side variable resistor circuit is configured as an NMOS transistor.

9. The resistor voltage divider circuit according to claim 8,
wherein
at least one of a low-potential-side MOS switch in the high-side variable resistor circuit and a high-potential-side MOS switch in the low-side variable resistor circuit is configured with a PMOS transistor and an NMOS transistor connected in parallel.

10. A differential amplifier comprising:
an operational amplifier;
a first input resistor having
a first terminal connected to an application terminal for a negative input voltage and
a second terminal connected to an inverting input terminal of the operational amplifier;
a feedback resistor having
a first terminal connected to an output terminal of the operational amplifier and
a second terminal connected to the second terminal of the first input resistor;
a second input resistor having
a first terminal connected an application terminal for a positive input voltage and
a second terminal connected to a non-inverting input terminal of the operational amplifier; and
a reference resistor having
a first terminal connected to the second terminal of the second input resistor and
a second terminal connected to an application terminal for a reference voltage,
wherein
the reference resistor includes the variable resistor circuit according to claim 1.

11. The differential amplifier according to claim 10,
wherein
the application terminal for the positive input voltage is configured to be connectable to a first terminal of a sense resistor for sensing a current, and
the application terminal for the negative input voltage is configured to be connectable to a second terminal of the sense resistor.

12. A motor driver comprising the differential amplifier according to claim 11, the motor driver being configured to drive a voice coil motor.
